(19) United States
(12) Patent Application Publication
(10) Pub. No.: US 2010/0003767 A1
(43) Pub. Date: Jan. 7, 2010

(54) MAGNETIC TUNNEL JUNCTION DEVICE, MEMORY CELL HAVING THE SAME, AND METHOD FOR FABRICATING THE SAME

(76) Inventor: Sang-Hoon Cho, Gyeonggi-do (KR)

Correspondence Address: IP & T Law Firm PLC, 7700 Little River Turnpike, Suite 207, Fairfax, VA, 22003, US

(21) Appl. No.: 12/492,406

(22) Filed: Jun. 26, 2009

(30) Foreign Application Priority Data
Jul. 3, 2008 (KR) 10-2008-0064396

(51) Int. Cl. H01L 21/00

(52) U.S. Cl. 438/3; 257/E21.001

(57) ABSTRACT

A method for fabricating a magnetic tunnel junction device includes forming an insulation layer having a plurality of openings, forming a first electrode over the bottom and the sidewall of an opening of the plurality of openings, forming a magnetic tunnel junction layer over the first electrode, and forming a second electrode over the magnetic tunnel junction layer to fill the remaining openings.

### CROSS-REFERENCE TO RELATED APPLICATIONS

The present invention claims priority of Korean patent application number 10-2008-0064396, filed on Jul. 3, 2008, the disclosure of which is incorporated herein by reference in its entirety.

### BACKGROUND OF THE INVENTION

The present invention relates to a semiconductor device fabricating method, and more particularly, to a magnetic tunnel junction (MTJ) device capable of preventing interference phenomenon between adjacent MTJ devices, a memory cell having the same, and a method for fabricating the same.

As a semiconductor device is becoming highly integrated, a magnetic random access memory (MRAM) is considered as the next generation semiconductor memory device having advantages such as simple cell region reduction, a high speed operation, and non-volatility. The MRAM includes a transistor for performing a switching operation and an MTJ device for storing information. In relation to the MTJ device, a magnetoresistance (MR) ratio is changed according to a magnetization direction of two ferromagnetic layers and it is determined whether information stored in the MTJ device is logic 1 or logic 0 through a voltage change or a current amount change based on a change of this MR ratio.

FIG. 1 is a cross-sectional view illustrating an MTJ device according to the prior art. Referring to FIG. 1, a first electrode 102, an MTJ layer 107, and a second electrode 108 are sequentially disposed on a substrate 101 having a predetermined structure. Herein, the MTJ layer 107 is a stacked layer where a pinning layer 103, a pinned layer 104, a tunnel insulation layer 105, and a free layer 106 are sequentially stacked. The pinning layer 103 is formed of an anti-ferromagnetic material and is disposed over the first electrode 102. The pinned layer 104 is formed of a ferromagnetic material and has a magnetization direction fixed by the pinning layer 103. The free layer 106 is formed of a ferromagnetic material and has a magnetization direction changed by external stimulus (e.g., a magnetic field or spin transfer torque (STT)).

After a photosensitive film pattern is formed on the second electrode 108, the second electrode 108, the MTJ layer 107, and the first electrode 102 are sequentially etched using the photosensitive film pattern as an etch barrier in order to form the MTJ device having a stack structure.

However, according to the typical MTJ device, it is desirable for the sidewall of the MTJ device to have a vertical profile during an etch process for forming the MTJ device. But, in reality, due to an etch selectivity between each thin layer, the MTJ device has a trapezoid shape with a slant sidewall. That is, due to the slant sidewall, the bottom interval S2 between adjacent MTJ devices becomes smaller than a predetermined top interval S1 (S1>S2). As the interval between adjacent MTJ devices is decreased, interference phenomenon therebetween may occur, where characteristics of the MTJ device are deteriorated. Additionally, when the interval S2 between adjacent MTJ devices is decreased even more, electrical short therebetween may occur, where characteristics of the MTJ device are deteriorated or the MTJ device cannot operate normally. These conditions worsen as dimensions of a semiconductor device are reduced based on design needs.

Moreover, as shown in ‘X’ of FIG. 1, an etch byproduct 109 occurring during an etch process for forming the MTJ device may be re-deposited on the sidewall of the MTJ device, such that characteristics of the MTJ device are deteriorated. Especially, when the conductive etch byproduct is re-deposited on the sidewall of the free layer 106 and the pinned layer 104, electrical short occurs therebetween such that characteristics of the MTJ device are deteriorated or the MTJ device cannot operate normally in severe conditions.

### SUMMARY OF THE INVENTION

Embodiments of the present invention are directed to provide a magnetic tunnel junction device capable of preventing interference phenomenon and electrical short between adjacent MTJ devices and a method for fabricating the same.

Embodiments of the present invention are also directed to provide an MTJ device capable of preventing characteristic deterioration of the MTJ device, which may be caused by a conductive etch byproduct occurring during an etch process for forming the MTJ device.

Embodiments of the present invention are also directed to provide a memory cell with an MTJ device.

In accordance with an aspect of the present invention, there is provided a method for fabricating a magnetic tunnel junction device, the method including: forming an insulation layer having a plurality of openings; forming a first electrode over the bottom and the sidewall of an opening of the plurality of openings; forming a magnetic tunnel junction layer over the first electrode; and forming a second electrode over the magnetic tunnel junction layer to fill the remaining openings.

The first electrode and the magnetic tunnel junction layer may have a cylindrical shape.

Forming the first electrode may include forming a conductive layer for the first electrode over an entire surface of the insulation layer including the opening; and leaving the conductive layer for the first electrode over the bottom and the sidewall of the opening by selectively etching the conductive layer formed over the top of the insulation layer.

Forming the magnetic tunnel junction layer may include forming a first magnetic layer over an entire surface of the insulation layer including the first electrode; leaving the first magnetic layer over the first electrode by selectively etching the first magnetic layer formed over the top of the insulation layer; sequentially forming a tunnel insulation layer and a second magnetic layer over an entire surface of the insulation layer including the patterned first magnetic layer; and leaving the second magnetic layer and the tunnel insulation layer over the first magnetic layer by selectively etching the second magnetic layer and the tunnel insulation layer formed over the top of the insulation layer.

Forming the magnetic tunnel junction layer may include sequentially forming a first magnetic layer, a tunnel insulation layer and a second magnetic layer over an entire surface of the insulation layer including the first electrode; and leaving the second magnetic layer, the tunnel insulation layer and the first magnetic layer over the first electrode by selectively etching the second magnetic layer, the tunnel insulation layer and the first magnetic layer formed over the top of the insulation layer.

Selectively etching the conductive layer may be performed using shallow etchback or chemical mechanical polishing.

Selectively etching the conductive layer using the chemical mechanical polishing may include forming a sacrificial layer to fill an inside of the opening and to cover the top of the insulation layer; performing chemical mechanical polishing until the top of the insulation is exposed; and removing the sacrificial layer.

The sacrificial layer may include a carbon containing layer or an oxide layer.

The carbon containing layer may include one of photoresist, amorphous carbon, SiOC, and SOC.

When the sacrificial layer may include the carbon containing layer, removing the sacrificial layer may be performed using O₂ plasma treatment.

When the sacrificial layer may include the oxide layer, removing the sacrificial layer is performed using a buffered oxide Etchant (BOE) solution or an HF solution.

### BRIEF DESCRIPTION OF THE DRAWINGS

FIG. 1 is a cross-sectional view illustrating a magnetic tunnel junction (MTJ) device according to prior art.

FIGS. 2A to 2D illustrate an MTJ device in accordance with a first embodiment of the present invention.

FIGS. 3A to 3E are schematic views comparing a conventional MTJ device having a stack structure with a pillar-type MTJ device in accordance with a first embodiment of the present invention.

FIGS. 4A and 4B illustrate a memory cell with an MTJ device in accordance with a second embodiment of the present invention.

FIGS. 5A and 5B illustrate a method of operating the memory cell in accordance with the second embodiment of the present invention.

FIGS. 6A and 6B illustrate a memory cell with an MTJ device in accordance with a third embodiment of the present invention.

FIGS. 7A to 7D are cross-sectional views illustrating a method of fabricating an MTJ device in accordance with a fourth embodiment of the present invention.

### DESCRIPTION OF SPECIFIC EMBODIMENTS

Other objects and advantages of the present invention can be understood by the following description, and become apparent with reference to the embodiments of the present invention.

Referring to the drawings, the illustrated thickness of layers and regions are exemplary and may not be exact. When a first layer is referred to as being “on” a second layer or “on” a substrate, it could mean that the first layer is formed directly on the second layer or the substrate, or it could also mean that a third layer may exist between the first layer and the substrate. Furthermore, the same or like reference numerals represent the same or like constituent elements, although they appear in different embodiments or drawings of the present invention.

The present invention below relates to a magnetic tunnel junction (MTJ) device, a memory cell having the same, and a method for fabricating the same. Provided is the MTJ device capable of preventing interference phenomenon and electrical short between MTJ devices by, for example, obtaining an interval between adjacent MTJ devices. For this, an example according to the present invention forms an MTJ device having a pillar-type concave structure.

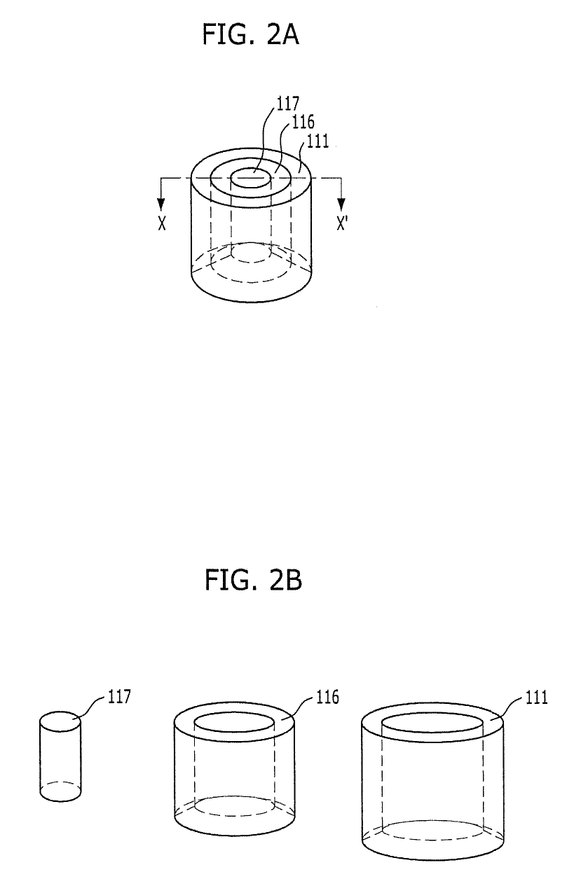

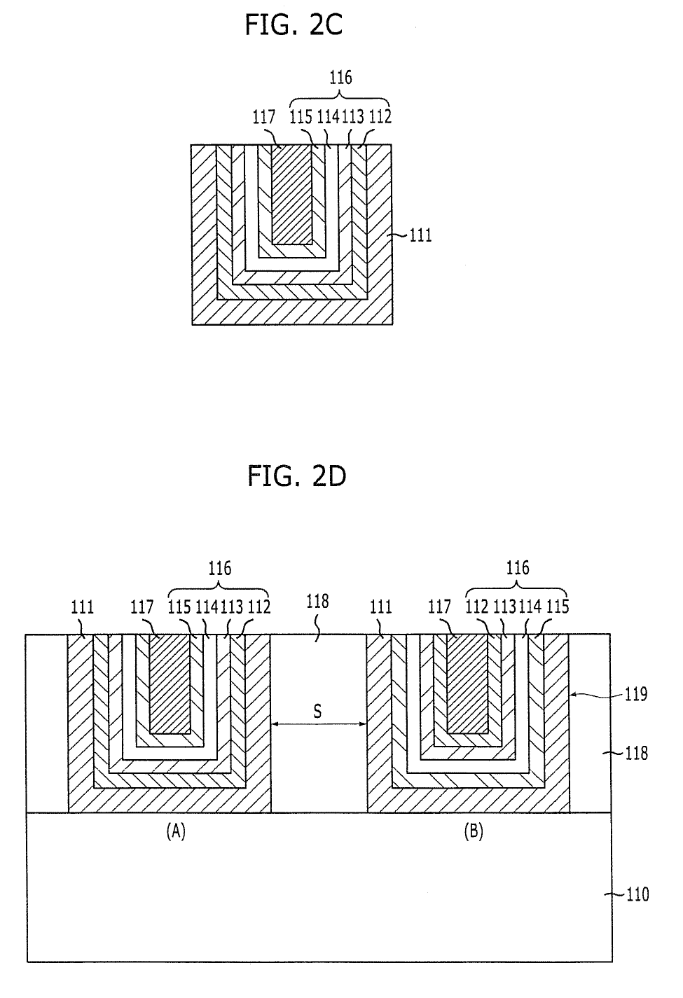

FIGS. 2A to 2D illustrate an MTJ device in accordance with a first embodiment of the present invention. FIG. 2A is a perspective view of a unit of the MTJ device. FIG. 2B is a perspective view illustrating each separated component of an MTJ device. FIG. 2C is a cross-sectional view taken along a line X-X′. FIG. 2D is a cross-sectional view illustrating an MTJ device having a concave structure. Referring to FIGS. 2A to 2D, the MTJ device of the present invention has a pillar-type concave structure. Specifically, the MTJ device includes a pillar-type second electrode 117, an MTJ layer 116 surrounding the side and the bottom of the second electrode 117, and a first electrode 111 surrounding the side and the bottom of the second MTJ layer 116. Herein, the second electrode 117 may have a circular cylinder shape, a tri-cylinder shape, or a polygonal cylinder shape. Additionally, the first electrode 111 and the MTJ layer 116 may have a cylindrical shape.

Additionally, the MTJ device of the present invention further includes a substrate 110 having a predetermined structure and an insulation layer 118. The insulation layer 118 is disposed over the substrate 110 and includes a plurality of opening parts 119 having a predetermined interval S. Herein, the MTJ device may have a concave structure filled in the opening part 119.

The insulation layer 118 electrically insulates the MTJ devices from each other and may be any one selected from the group consisting of an oxide layer, a nitride layer, an oxynitride layer, a carbon containing layer, and stacked layers of the foregoing layers. The oxide layer may be formed of SiO₂, boron phosphorus silicate glass (BPSG), phosphorus silicate glass (PSG), tetra ethyle ortho silicate (TEOS), un-doped silicate glass (USG), spin on glass (SOG), high-density plasma (HDP), or spin on dielectric (SOD). The nitride layer may be formed of Si₃N₄. The oxide nitride layer may be formed of SiON. Additionally, a carbon containing layer may be formed of amorphous carbon, carbon rich polymer, SiOC, or SOC.

The opening part 119 having a predetermined interval S serves to prevent interference phenomenon and electrical short between adjacent MTJ devices. Additionally, the opening part 119 serves to prevent the MTJ device from having a slant sidewall and to obtain an interval S between adjacent MTJ devices simultaneously. Herein, it is desirable that the side of the MTJ device have a vertical profile, in order to effectively prevent interference phenomenon and electrical short between adjacent MTJ devices, which may be caused by a slant sidewall.

The MTJ layer 116 includes a free layer 115 surrounding the side and the bottom of the second electrode 117, a tunnel insulation layer 114 surrounding the side and the bottom of the free layer 115, a pinned layer 113 surrounding the side and the bottom of the tunnel insulation layer 114, and a pinning layer 112 surrounding the side and the bottom of the pinned layer 113 (see a portion A of FIG. 2D). Additionally, the MTJ layer 116 includes a pinning layer 112 surrounding the side and the bottom of the second electrode 117, a pinned layer 113 surrounding the side and the bottom of the pinning layer 112, a tunnel insulation layer 114 surrounding the side and the bottom of the pinned layer 113, and a free layer 115 surrounding the side and the bottom of the tunnel insulation layer 114. Herein, the free layer 115, the tunnel insulation layer 114, the pinned layer 113, and the pinning layer 112 may have a cylindrical shape.

The first electrode 111 and the second electrode 117 may be formed of a conductive material such as a metal material or a metal compound. The metal material includes Ti, Ta, Pt, Cu, W, or Al. The metal compound includes TiN, TaN, or WSi. Additionally, the first electrode 111 and the second electrode 117 may be formed of the same material.

The pinning layer 112 serves to fix a magnetization direction of the pinned layer 113, and may be formed of an anti-ferromagnetic material. The anti-ferromagnetic material includes IrMn, PtMn, MnO, MnS, MnTe, MnF₂, FeF₂, FeCl₂, FeO, CoCl₂, CoO, NiCl₂, or NiO. Herein, the pinning layer 112 may be a single layer or stacked layers of the foregoing layers. The single layer is formed of one of the above anti-ferromagnetic materials.

The pinned layer 113 having a magnetization direction fixed by the pinning layer 112 and the free layer 115 having a magnetization direction changed by external stimulus (e.g., a magnetic field or spin transfer torque (STT)) may be formed of a ferromagnetic material. The ferromagnetic material includes Fe, Co, Ni, Gd, Dy, NiFe, CoFe, MnAs, MnBi, MnSb, CrO₂, MnOFe₂O₃, FeOFe₂O₃, NiOFe₂O₃, CuOFe₂O₃, MgOFe₂O₃, EuO, or Y₃Fe₅O₁₂. Herein, the pinned layer 113 and the free layer 115 may be a single layer or stacked layers of the foregoing layers. The single layer is formed of one of the above ferromagnetic materials. Additionally, the pinned layer 113 and the free layer 115 may include a stacked layer where one of the above ferromagnetic materials and a Ru layer are stacked sequentially, for example, CdFe/Ru/CoFe. Moreover, the pinned layer 113 and the free layer 115 may include a synthetic anti-ferromagnetic (SAF) layer where a ferromagnetic layer, an anti-ferromagnetic coupling spacer layer, and a ferromagnetic layer are sequentially stacked.

The tunnel insulation layer 114 serves as a tunneling barrier between the pinned layer 113 and the free layer 115. The tunnel insulation layer 114 may be formed of MgO, Al₂O₃, Si₃N₄, SiON, SiO₂, HfO₂, or ZrO₂. Also, the tunnel insulation layer 114 may be formed of any material having an insulation characteristic.

Moreover, the MTJ device of the present invention may further include a capping layer (not shown) interposed between the second electrode 117 and the MTJ layer 116. The capping layer serves to prevent a material, that is, a metal material or a metal compound material, constituting the free layer 115 from being oxidized or eroded, which is caused by fabricating errors during an MTJ device fabricating process. The capping layer may be formed of Ta or TaN.

Specifically, when a material constituting the free layer 115 is oxidized or eroded because of the fabricating errors, a magnetoresistance (MR) ratio of the MTJ device may be deteriorated. Due to this, characteristics of memory cells constituting the MTJ device may be deteriorated. However, this can be prevented using the capping layer. In this disclosure, the MR ratio means a value defined by [(high resistance state value−low resistance state value)/low resistance state value]×100.

Additionally, the MTJ device of the present invention may further include an exothermic layer (not shown) interposed between the second electrode 117 and the MTJ layer 116, or between the MTJ layer 116 and the first electrode 111. The exothermic layer provides thermal energy to the MTJ device in order to reduce the critical current density of the MTJ device. In this disclosure, the critical current density means the minimum current density necessary for changing the MR ratio of the MTJ device. As the critical current density is decreased, power consumption for operating the MTJ device can be reduced also. The exothermic layer may include one selected from the group consisting of an Al₂O₃ layer, an un-doped silicon layer, a silicon carbide layer, a SiO₂ layer, a SiON layer, a chalcogenide layer, and stacked layers of the foregoing layers. The chalcogenide layer may be a compound layer containing germanium (Ge), stibium (sb), and tellurium (Te) (that is, a GST layer).

In this manner, the present invention provides the MTJ device having a cylindrical MTJ layer 116. Therefore, interference phenomenon and electrical short, which caused by the slant sidewall of the MTJ device, can be prevented. This will be described in more detail in an MTJ device fabricating method that will be mentioned later.

Additionally, the MTJ device of the present invention has a concave structure filled in the opening part 119, such that interference phenomenon and electrical short, which are caused by a slant sidewall of the MTJ device, can be effectively prevented and an interval between adjacent MTJ devices can be stably obtained at the same time.

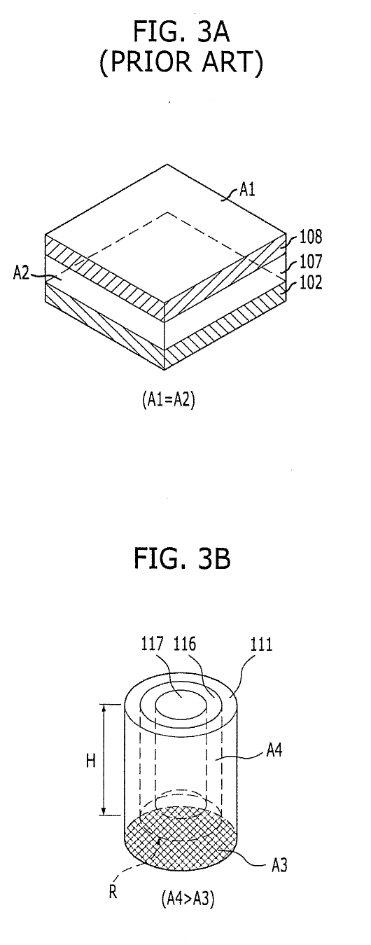

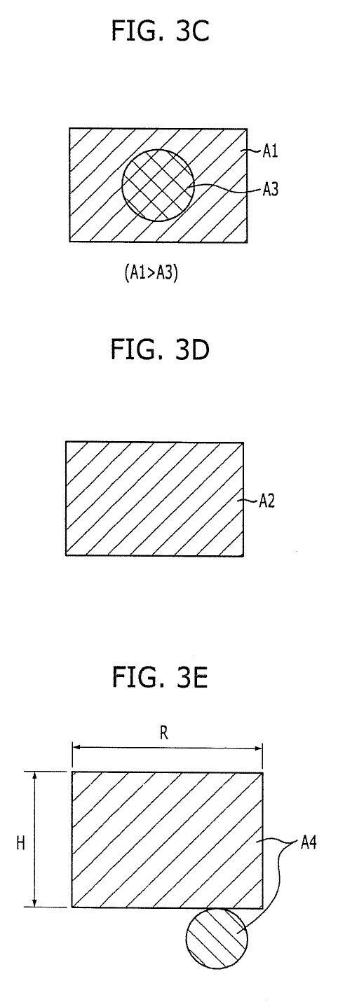

Moreover, since the MTJ device of the present invention has a pillar structure, the integration degree of the MTJ device is improved and characteristics of the MTJ device are enhanced. This will be described in more detail with reference to FIGS. 3A to 3E.

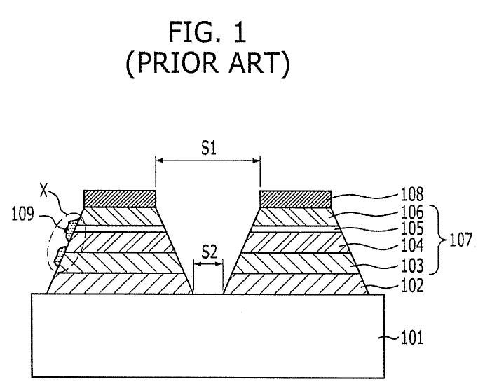

FIGS. 3A to 3E are schematic views when a conventional MTJ device having a stack structure is compared with a pillar-type MTJ device in accordance with a first embodiment of the present invention. For illustration purposes, the conventional MTJ device having a stack structure in accordance with prior art shown in FIG. 3A uses the same reference numerals as FIG. 1. The conventional MTJ device having a stack structure has the same volume as the pillar-type MTJ device of the present invention shown in FIG. 3B. Herein, A1 represents area of the conventional MTJ device when the MTJ device is seen from the top; A2 represents contact area between the MTJ layer 107 and the first electrode 102 in the conventional MTJ device; A3 represents area of the pillar-type MTJ device when the pillar-type MTJ device is seen from the top; and A4 represents contact area between the MTJ layer 116 and the first electrode 111 in the pillar-type MTJ device.

Before the conventional MTJ device having a stack structure is compared with the pillar-type MTJ device of the present invention, limitations of the typical MTJ device having a stack structure due to the design rule reduction of a semiconductor device are as follows.

As a design rule of a semiconductor device is reduced, an MTJ device needs to be highly integrated in order to improve performances (e.g., an operation speed and a storage capacity) of a memory cell having the MTJ device. Due to this, an A1 of the MTJ device is gradually decreased. As the A1 of the MTJ device is decreased, an A2 of the MTJ layer 107 is also decreased. Since the MTJ device has a stack structure, the A1 of the MTJ device is identical to the A2 of the MTJ layer 107 (that is, A1=A2) as shown in FIG. 3A.

In the same manner, as the area of the MTJ device is decreased, the area of the MTJ layer 107 is also decreased. Thus, electrical characteristics of the MTJ device can be deteriorated. In more detail, the MTJ device has an MR ratio that is determined according to a magnetization direction of a pinned layer (not shown) and a free layer (not shown), which are ferromagnetic thin layers. Herein, as the area of the ferromagnetic layer is decreased, a magnetic domain size is reduced. Thus, saturation magnetization is increased. As the critical current density of the MTJ device is increased, an operation current density necessary for changing an MR ratio of the MTJ device is also increased. Therefore, power consumption of a Magnetic Random Access Memory (MRAM) including the MTJ device is increased. Moreover, as the critical current density of the MTJ device is increased, when a required driving current density is applied, it is difficult to reduce a transistor size and a wiring size. Therefore, the integration degree of a memory cell including an MTJ device is deteriorated.

As shown in FIG. 3B, since the MTJ device of the present invention has a pillar shape, limitations of the MTJ device having a stack structure due to the above-mentioned design rule reduction of a semiconductor device can be resolved.

Specifically, when the MTJ device having a stack structure in accordance with prior art and the pillar-type MTJ device in accordance with the present invention have the same volume, as illustrated in FIGS. 3A to 3E, the pillar-type MTJ device of the present invention can reduce an area without difficulties, compared to the MTJ device having a stack structure in accordance with prior art. That is, an A3 of the pillar-type MTJ device in accordance with the present invention is smaller than the A1 of the MTJ device having a stack structure in accordance with prior art (A1>A3) as shown in FIG. 3C.

Additionally, the A2 of the MTJ layer 107 in the MTJ device having a stack structure in accordance with prior art is identical to the A1 of the MTJ device as shown in FIG. 3D. As the A1 of the MTJ device is decreased, the A2 of the MTJ layer 107 is decreased also.

Compared to that, the A3 of the MTJ device is reduced and the height H of the MTJ device is increased in the pillar-type MTJ device of the present invention. An A4 of the MTJ layer 116 can be increased as shown in FIG. 3E. The reason is that the A4 of the MTJ layer 116 is determined by the circumference R and the height H in the MTJ device of the present invention. Herein, the A4 is larger than the A2 (A4>A2).

In addition, when the circumference R is lengthened to increase the A4 of the MTJ layer 116 in the MTJ device of the present invention, since there is possibility that the A3 of the MTJ device is increased, it is desirable to increase the A4 of the MTJ layer 116 by increasing the height H.

In the same manner, the pillar-type MTJ device of the present invention reduces the A3 and increases the A4 of the MTJ layer 116 at the same time. Through this, even if the A3 of the MTJ layer 116, especially, the area of the pinned layer and the free layer formed of a ferromagnetic thin layer, is reduced, the critical current density of the MTJ device is not increased.

As mentioned above, since the MTJ device of the present invention has a pillar shape, the integration degree of the MTJ device can be improved and electrical characteristics of the MTJ device can be enhanced at the same time.

Hereafter, a memory cell including the pillar-type MTJ device of the present invention will be described with reference to the accompanying drawings. In general, an MR ratio of the MTJ device is determined by a magnetization direction of a free layer. Accordingly, based on a driving principle (for example, a magnetic field or STT) that changes a magnetization direction of the free layer, a structure of a memory cell including the MTJ device may be different. In a second embodiment of the present invention that will be mentioned later, a memory cell using STT as a driving principle for changing a magnetization direction of a free layer is exemplified. In this disclosure, the STT can be described with reaction of giant magnetoresistive (GMR). According to Newton's third law (that is, a law of action and reaction), action is inevitably followed by corresponding reaction having the same magnitude and a reverse direction to the action. Herein, the GMR is a phenomenon that occurs because a current amount can be adjusted by a magnetization direction. As reaction according thereto, it is possible to adjust a magnetization direction through current (for example, spin current) and this is called STT.

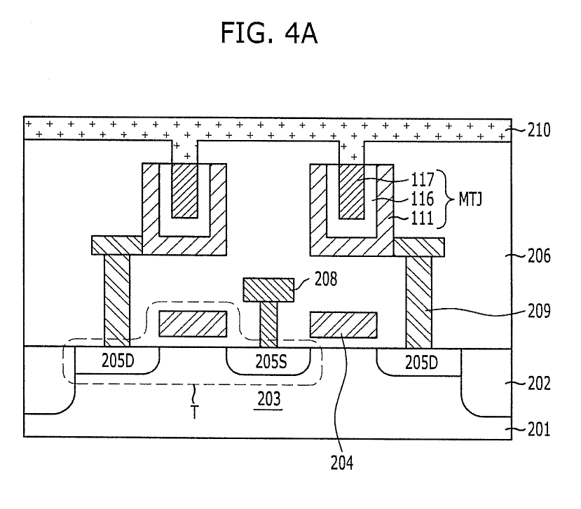

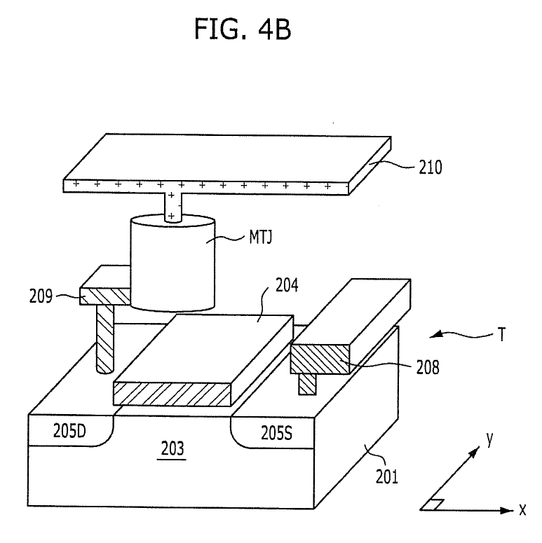

FIG. 4A is a cross-sectional view illustrating a memory cell with an MTJ device in accordance with a second embodiment of the present invention. FIG. 4B is a perspective view illustrating a unit cell of the memory cell of FIG. 4A. Referring to FIGS. 4A and 4B, a device isolation layer 202 is disposed in a predetermined region of a substrate 201 to define an active region 203. A plurality of gate electrodes 204 (that is, a word line) crossing over the active region 203 and the device isolation layer 202 at the same time are disposed on the substrate 201 including the device isolation layer 202. Herein, when a direction of the active region 203 is designated as a row direction which is the x-axis direction a gate electrode 204 is disposed in a column direction which is the y-axis direction. A common source region 205S is disposed in the substrate 201 of the active region 203 between the gate electrodes 204, and a drain region 205D is disposed in the substrate 201 of the active region 203 at the both sides of the common source region 205S. Accordingly, a transistor T for performing a switching operation is formed on a point where the active region 203 and the gate electrode 204 intersect.

An interlayer insulation layer 206 covers an entire surface of the substrate 201 having the transistor T. A conductive line 210 crossing over the gate electrode 204 and connected to the second electrode 117 of the MTJ device is disposed over the interlayer insulation layer 206. The conductive line 210 is commonly called a bit line.

Additionally, a vertical wiring 209 that electrically connects the first electrode 111 of the MTJ device with the drain region 205D of the transistor T is disposed in the interlayer insulation layer 206. The vertical wiring 209 may include sequentially stacked plugs. Additionally, the source line 208 is sequentially connected to the top of the common source region 205S.

The MTJ device may have a concave structure of a pillar shape. Specifically, the MTJ device includes a pillar-type second electrode 117, an MTJ layer 116 surrounding the side and the bottom of the second electrode 117, and a first electrode 111 surrounding the side and the bottom of the MTJ layer 116. Herein, the second electrode 117 may have a circular cylinder shape, a tri-cylinder shape, or a polygonal cylinder shape. Additionally, the first electrode 111 and the MTJ layer 116 may have a cylinder shape. Additionally, the MTJ device may further include a capping layer (not shown) interposed between the second electrode 117 and the MTJ layer 116. Moreover, the MTJ device may further include an exothermic layer (not shown) interposed between the second electrode 117 and the MTJ layer 116 or between the MTJ layer 116 and the first electrode 111.

Since the MTJ device of the second embodiment is already described in detail with reference to FIGS. 2A to 2D, its detailed description will be omitted for conciseness.

The gate electrode 204, the source line 208, the conductive line 210, and the vertical wiring may include one selected from a polysilicon layer, a metal layer, a conductive metal nitride layer, a conductive metal oxide layer, and a metal silicide layer, and stacked layers of the foregoing layers, which include a conductive material. The metal layer may be formed of Ti, Ta, W, Cu, or Al. The conductive metal nitride layer may be formed of TiN or TaN. The conductive metal oxide layer may be formed of IrO₂. Additionally, the metal suicide layer may be formed of TiSi or WSi.

The interlayer insulation layer 206 may be one selected from the group consisting of an oxide layer, a nitride layer, an oxynitride layer, a carbon containing layer, and stacked layers of the foregoing layers. The oxide layer may be formed of SiO₂, BPSG, PSG, TEOS, USG, SOG, HDP, or SOD. The nitride layer may be formed of Si₃N₄. The oxide nitride layer may be formed of SiON. Additionally, a carbon containing layer may be formed of amorphous carbon, carbon rich polymer, SiOC, or SOC.

In the same manner, since the memory cell of the present invention includes a pillar-type MTJ device that can be highly integrated, the integration degree of a memory cell can be improved. Through this, an operation speed and a storage capacity of the memory cell can be improved.

Additionally, since the MTJ device of the present invention has a pillar shape, its critical current density can be reduced. Through this, an operation current density of the memory cell also can be reduced. As the operation current density of the memory cell is decreased, power consumption of the memory cell can be reduced. Moreover, the size of the transistor T and wirings (that is, a conductive line and a word line) constituting the memory cell can be decreased by reducing the operation current density. Through this, the integration degree of the memory cell can be improved more.

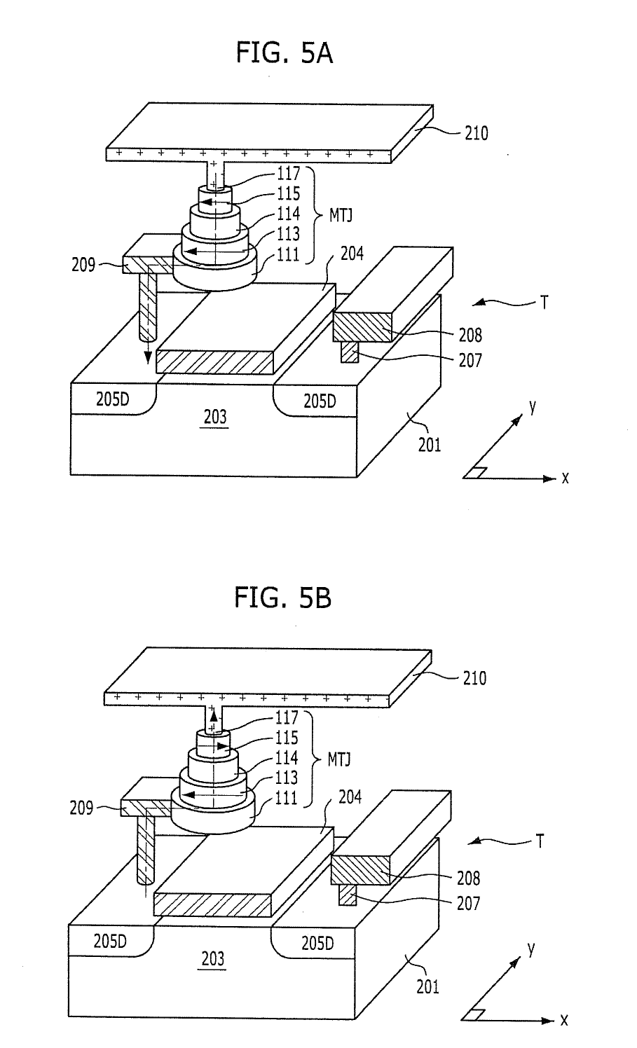

In the memory cell having the above mentioned structure in accordance with the second embodiment of the present invention, a magnetization direction of a free layer is changed according to STT of current flowing through the MTJ device and thus a magnetization direction of the free layer is determined according to a direction of current flowing through the free layer. A method of driving the memory cell in accordance with the second embodiment of the present invention will be described in more detail with reference to FIGS. 5A and 5B.

FIGS. 5A and 5B are schematic views illustrating a method of operating the memory cell in accordance with the second embodiment of the present invention. For illustration purposes, the MTJ device is shown with a step shape, and a pinning layer is not shown. Moreover, it is assumed that a magnetization direction of a free layer 115 is fixed to the right direction and a magnetization direction of a pinned layer 113 is fixed to the left direction.

Referring to FIG. 5A, when a source line 208 is grounded, a word line signal (for example, a voltage) is applied to the gate electrode 204 of the transistor T in order to activate (that is, turn on) the transistor T. Herein, when a conductive line signal is greater than the ground (that is, a positive voltage is applied to the conductive line 210), current flows through the MTJ device due to a voltage difference between the conductive line 210 and the source line 208. When the current density of the induced current is greater than the critical current density of the MTJ device, a magnetization direction of the free layer 115 is changed to the left or right direction. According to an example, a magnetization direction of the free layer 115 is changed from the right to the left by a current flowing from the second electrode 117 to the first electrode 111.

Referring to FIG. 5B, when the source line 208 is grounded, the transistor T is activated, and a conductive line signal having a negative voltage is applied to the conductive line 210, current flows through the MTJ device due to a voltage difference between the conductive line 210 and the source line 208. When the current density of the induced current is greater than the critical current density of the MTJ device, a magnetization of the free layer 115 is changed to the left or right direction. According to an example, a magnetization direction of the free layer 115 is changed from the left to the right by a current flowing from the first electrode 111 to the second electrode 117.

When magnetization directions of the pinned layer 113 and the free layer 115 are the same (see FIG. 5A), an MR ratio of the MTJ device is less than when magnetization directions of the pinned layer 113 and the free layer 115 are different from each other (see FIG. 5B). By sensing that, logic ‘0’ or logic ‘1’ can be determined. In order to determine logic ‘0’ and logic ‘1’, it is desirable that the current density of a current generated by a voltage difference between the source line 208 and the conductive line 210 when the transistor T is activated is less than the critical current density of the MTJ.

Additionally, although not illustrated, when a word line signal is not applied to the gate electrode 204 (that is, the transistor T is in an inactivation state (that is, turned off)), even if a conductive line signal is applied to the conductive line 210, current does not flow in the MTJ device. Accordingly, a magnetization direction of the free layer 115 cannot be changed when the transistor T is in an inactivation state.

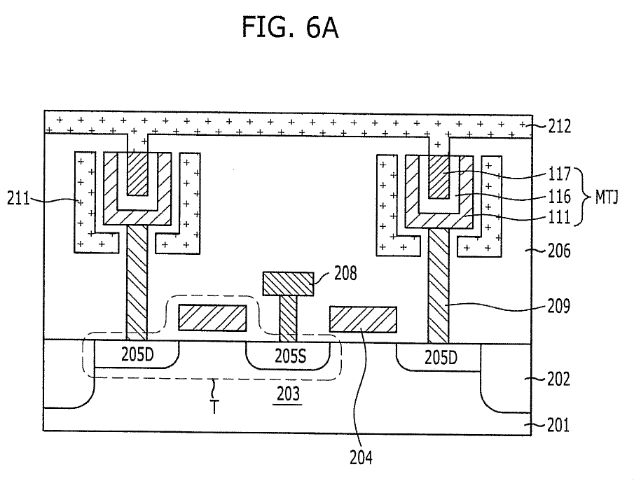

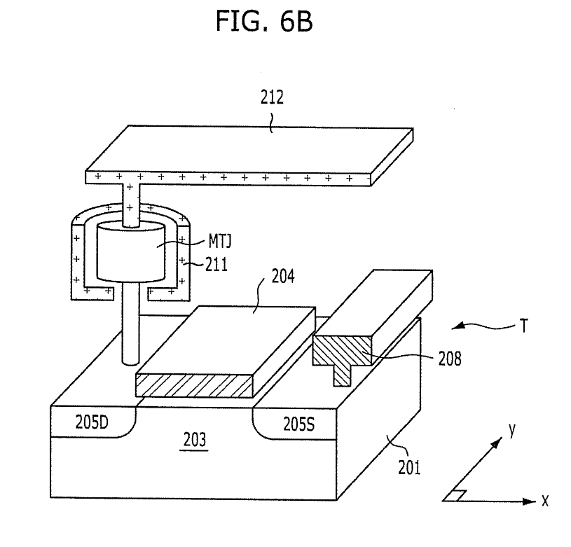

Hereafter, a memory cell including the pillar-type MTJ device of the present invention and changing an MR ratio of the MTJ device through a magnetic field will be described in more detail with reference to FIGS. 6A and 6B.

FIG. 6A is a cross-sectional view illustrating a memory cell with an MTJ device in accordance with a third embodiment of the present invention. FIG. 6B is a perspective view illustrating a unit cell of the memory cell of FIG. 6A. Referring to FIGS. 6A and 6B, a device isolation layer 202 is disposed on a predetermined region of a substrate 201 to define an active region 203. A plurality of gate electrodes 204 (that is, a word line) crossing over the active region 203 and the device isolation layer 202 at the same time are disposed on the substrate 201 including the device isolation layer 202. Herein, when a direction of the active region 203 is designated as a row direction which is the x-axis direction, a gate electrode 204 is disposed in a column direction which is the y-axis direction. A common source region 205S is disposed in the substrate 201 of the active region 203 between the gate electrodes 204, and a drain region 205D is disposed in the substrate 201 of the active region 203 at both sides of the common source region 205S. Accordingly, a transistor T for performing a switching operation is formed at a point where the active region 203 and the gate electrode 204 intersect.

An interlayer insulation layer 206 covers an entire surface of the substrate 201 having the transistor T. A second conductive line 212 crossing over the gate electrode 204, which is in the x-axis direction and connected to the second electrode 117 of the MTJ device, is disposed on the interlayer insulation layer 206. The second conductive line 212 is commonly called a bit line.

A first conductive line 211, which partially surrounds the side and the bottom of the first electrode 111 of the MTJ device and is electrically insulated from the first electrode 111, is disposed in the interlayer insulation layer 206. The first conductive line 211 is commonly called a digit line and is disposed in a direction which is the y-axis direction parallel to the gate electrode 204.

A vertical wiring 209 that electrically connects the first electrode 111 of the MTJ device with the drain region 205D of the transistor T is disposed in the interlayer insulation layer 206. The vertical wiring 209 may include sequentially stacked plugs. Additionally, the source line 208 is sequentially connected on the common source region 205S.

The MTJ device may have a concave structure of a pillar shape. Specifically, the MTJ device includes a pillar-type second electrode 117, an MTJ layer 116 surrounding the side and the bottom of the second electrode 117, and a first electrode 111 surrounding the side and the bottom of the MTJ layer 116. Herein, the second electrode 117 may have a circular-cylinder shape, a tri-cylinder shape, or a polygonal-cylinder shape. Additionally, the first electrode 111 and the MTJ layer 116 may have a cylinder shape. Additionally, the MTJ device may further include a capping layer (not shown) interposed between the second electrode 117 and the MTJ layer 116. Moreover, the MTJ device may further include an exothermic layer (not shown) interposed between the second electrode 117 and the MTJ layer 116 or between the MTJ layer 116 and the first electrode 111.

Since the MTJ device of the third embodiment is already described in detail with reference to FIGS. 2A to 2D, its detailed description will be omitted for conciseness.

The gate electrode 204, the source line 208, the first and second conductive lines 211 and 212, and the vertical wiring may include one selected from a polysilicon layer, a metal layer, a conductive metal nitride layer, a conductive metal oxide layer, and a metal silicide layer, and stacked layers of the foregoing layers, which include a conductive material. The metal layer may be formed of Ti, Ta, W, Cu, or Al. The conductive metal nitride layer may be formed of TiN or TaN. The conductive metal oxide layer may be formed of IrO₂. Additionally, the metal silicide layer may be formed of TiSi or WSi.

The interlayer insulation layer 206 may be one selected from the group consisting of an oxide layer, a nitride layer, an oxynitride layer, a carbon containing layer, and stacked layers of the foregoing layers. The oxide layer may be formed of SiO₂, BPSG, PSG, TEOS, USG, SOG, HDP, or SOD. The nitride layer may be formed of Si₃N₄. The oxide nitride layer may be formed of SiON. Additionally, a carbon containing layer may be formed of amorphous carbon, carbon rich polymer, SiOC, or SOC.

As described above, since the memory cell of the present invention includes a pillar-type MTJ device that can be highly integrated, the integration degree of a memory cell can be improved. Thus, an operation speed and a storage capacity of the memory cell can be enhanced.

Additionally, since the MTJ device of the present invention has a pillar shape, its critical current density can be reduced. As a consequence, an operation current density of the memory cell also can be reduced. As the operation current density of the memory cell is decreased, power consumption of the memory cell can be reduced. Moreover, the size of the transistor T and wirings, which are a conductive line and a word line, constituting the memory cell can be decreased by reducing the operation current density. As a consequence, the integration degree of the memory cell can be improved more.

The memory cell with the above structure in accordance with the third embodiment of the present invention may change an MR ratio of the MTJ device using a magnetic field. The magnetic field is induced around the first and second conductive lines 211 and 212 by a current flowing through the first conductive line 211 and the second conductive line 212. For example, when a current direction of the first conductive line 211 is fixed, by adjusting a direction of current flowing through the second conductive line 212, an MR ratio of the MTJ device can be changed. Specifically, when an intensity of a magnetic field induced around the second conductive line 212 by a current flowing through the second conductive line 212 is greater than saturation magnetization of the free layer, a magnetization direction of the free layer is changed to the same direction as a current flowing through the second conductive line 212, and through this, the MR ratio of the MTJ device can be changed. Besides that, there are various known techniques about a method of changing the MR ratio of the MTJ device using a magnetic field induced around the first and second conductive lines 211 and 212, and thus its detailed description will be omitted.

Hereafter, a method of fabricating the pillar-type MTJ device of the present invention will be described in more detail with reference to the accompanying drawings. In the process described below, a description of well known techniques for manufacturing a semiconductor device or manufacturing a layer related thereto that are not necessary for explaining embodiments of the invention will be omitted. Further, embodiments of the present invention are not limited by the well-known techniques.

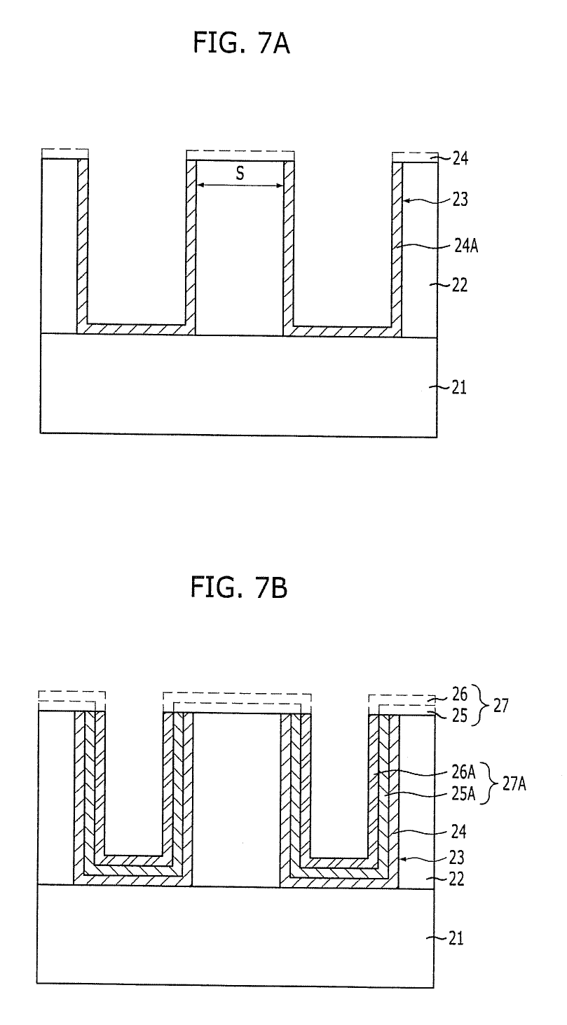

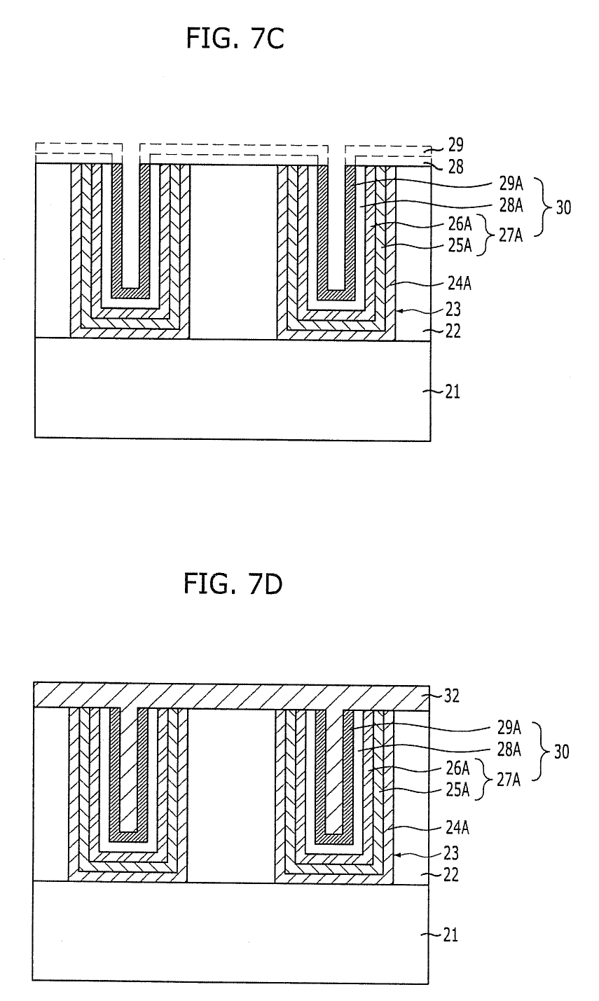

FIGS. 7A to 7D are fabricating sectional views illustrating a method of fabricating an MTJ device in accordance with a fourth embodiment of the present invention. Referring to FIG. 7A, an insulation layer 22 having a plurality of opening parts 23 with a predetermined interval S is formed over a substrate 21 having a predetermined structure. Herein, the opening part 23 is a region where an MTJ device is to be formed by the process described below, and it is desirable that the interval S is obtained to prevent interference phenomenon between adjacent MTJ devices. Additionally, in order to prevent interference phenomenon and electrical short due to a slant sidewall of the MTJ device, it is desirable that the side wall of the MTJ device has a vertical profile.

In addition, although not illustrated in the drawings, the opening part 23 may be formed to expose a predetermined structure of the substrate 21, for example, the top surface of wiring connected to a junction region of a transistor (see FIGS. 4A, 4B, 6A, and 6B).

The insulation layer 22 may be one selected from the group consisting of an oxide layer, a nitride layer, an oxynitride layer, a carbon containing layer, and stacked layers of the foregoing layers. The oxide layer may be formed of SiO₂, BPSG, PSG, TEOS, USG, SOG, HDP, or SOD. The nitride layer may be formed of Si₃N₄. The oxide nitride layer may be formed of SiON. Additionally, a carbon containing layer may be formed of amorphous carbon, carbon rich polymer, SiOC, or SOC. Besides that, the insulation layer 22 may be formed of any material having an insulation characteristic.

A conductive layer for a first electrode 24 is formed over an entire surface of the insulation layer 22 including the opening part 23. The conductive layer for a first electrode 24 may be formed of a conductive material, for example, a metal material or a metal compound. The metal material includes Ti, Ta, Pt, Cu, W, or Al. The metal compound includes TiN, TaN, or WSi.

The conductive layer for a first electrode 24 over the top surface of the insulation layer 22 is selectively etched to leave the conductive layer for a first electrode 24 at the bottom and the sidewall of the opening part 23. Herein, the conductive layer for a first electrode 24 remaining on the bottom and the sidewall of the opening part 23 serves as a first electrode 24A. Hereinafter, an etch process for forming the first electrode 24A is shortly called a first etch process.

The first etch process may be performed using etchback or chemical mechanical polishing (CMP). Here, when the first etch process is performed using the etchback, in order to prevent the conductive layer for a first electrode 24 at the bottom and sidewall of the opening part 23 from being damaged, it is desirable to perform the first etch process using shallow etchback.

A method of performing the first etch process through the shallow etchback is as follows.

The shallow etchback is performed through an etch method using chemical dry etch (CDE). The CDE is a method that can perform chemical etch and physical etch at the same time. The physical etch generates plasma using inert gas such as Ar, He, Xe, and so forth, and allows positive ions of the plasma to be vertically incident to a wafer in order to physically and clearly etch a target etch layer. The chemical etch selects gas that chemically easily react in the target etch layer and in a plasma state in order to generate plasma, and also chemically and clearly etch the target etch layer using a neutral radical activated in the plasma. Accordingly, the CDE method performing the chemical etch and physical etch simultaneously allows positive ions in plasma to be incident to a wafer in order to use strong collision energy of the positive ions, and also allows an etch speed to be increased by one order using the radical that chemically and easily reacts on the target etch layer. Thus, a synergy effect can be achieved. Herein, according to the CDE method, when the chemical etch is stronger than the physical etch, the target etch layer is etched more in a parallel direction compared to a vertical direction, and when the physical etch is stronger than the chemical etch, the target etch layer is etched more in a vertical direction compared to a parallel direction,

The shallow etchback selectively etches the conductive layer for a first electrode 24 formed on the top surface of the insulation layer 23 by adjusting at least one process condition of a process condition group consisting of a source power, a bias power, pressure of a plasma etch device, a temperature of a top electrode, a temperature of the bottom electrode, and a ratio of physical etch gas and chemical etch gas supplied in chamber. For example, when argon gas (that is, physical etch gas) is used as etch gas, the conductive layer for a first electrode 24 formed at the bottom and sidewall of the opening part 23 is not damaged during the first etch process when a bias power is not applied and an internal pressure of the opening part 23 is increased. This is because argon positive ions formed by plasma lose its acceleration energy because of an internal pressure of the opening part 23.

A method of performing the first etch process through a CMP process is as follows.

A sacrificial layer (not shown) is formed to fill the opening part 23 and cover an entire surface of the conductive layer for a first electrode 24. Herein, the sacrificial layer serves to prevent the damage of the conductive layer for a first electrode 24 formed at the bottom and sidewall of the opening part 23 during the first etch process, and may be formed of a carbon containing layer or an oxide layer. The carbon containing layer may be formed of one selected from the group consisting of photoresist (PR), an amorphous carbon layer, SiOC, and SOC. The oxide layer may be formed of SiO₂, BPSG, PSG, TEOS, USG, HDP, SOG, or SOD.

The CMP process is performed until the top surface of the insulation layer 22 is exposed, in order to leave the conductive layer for a first electrode 24 at the bottom surface and sidewall of the opening part 23.

The sacrificial layer is removed. When the sacrificial layer is formed of a carbon containing layer, an O₂ plasma treatment is used to remove the sacrificial layer. When the sacrificial layer is formed of an oxide layer, a wet etch method using a buffered oxide etchant (BOE) solution or an HF solution is used to remove the sacrificial layer. Herein, during the removing of the sacrificial layer, a cleansing process may be simultaneously performed to remove etch byproduct occurring the first etch process.

Through the above-mentioned fabricating process, the first electrode 24A having a cylindrical shape, which is filled in the opening part 23, may be formed. Herein, in order to simplify the fabricating process of the MTJ device, it is desirable that the first etch process is performed through the etchback.

Referring to FIG. 7B, a first magnetic layer 27 is formed over an entire surface of the insulation layer 22 including the first electrode 24A. The first magnetic layer 27 may have a structure where the pinning layer 25 and the pinned layer 26 are sequentially stacked.

The pinning layer 25 serves to fix a magnetization direction of the pinned layer 26, and may be formed of an anti-ferromagnetic material. For example, the anti-ferromagnetic material may include IrMn, PtMn, MnO, MnS, MnTe, MnF₂, FeF₂, FeCl₂, FeO, COCl₂, CoO, NiCl₂, or NiO. The pinning layer 25 may include a single layer formed of any one of the above-mentioned materials or stacked layers of the foregoing layers.

The pinned layer 26 having a magnetization direction fixed by the pinning layer 25 may be formed of a ferromagnetic material. For example, the ferromagnetic material includes Fe, Co, Ni, Gd, Dy, NiFe, CoFe, MnAs, MnBi, MnSb, CrO2, MnOFe₂O₃, FeOFe₂O₃, NiOFe₂O₃, CuOFe₂O₃, MgOFe₂O₃, EuO, or Y₃Fe₅O₁₂. The pinned layer 26 may include a single layer formed of any one of the above mentioned ferromagnetic materials or stacked layers of one or more of the foregoing layers. Additionally, the pinned layer 26 may be a stacked layer where any one of the above mentioned ferromagnetic materials and a Ru layer are sequentially stacked (for example, CdFe/Ru/CoFe). Moreover, the pinned layer 26 may be formed of a SAF layer where a ferromagnetic layer, an anti-ferromagnetic coupling spacer layer, and a ferromagnetic layer are sequentially stacked.

The first magnetic layer 27 over the top surface of the insulation layer 22 is selectively etched to leave the first magnetic layer 27 on the bottom and sidewall of the opening 23. Hereafter, an etch process for patterning the first magnetic layer 27 is simply called a second etch process. Additionally, the reference number of the patterned first magnetic layer 27 is changed into 27A. The reference number of the pinning layer 25 is changed into 25A. The reference number of the pinned layer 26 is changed into 26A.

The second etch process can be performed using the same method as the first etch process such as the etchback or the CMP. When the second etch process is performed using the etchback, it is desirable that the shallow etchback is used to prevent the damage of the first magnetic layer 27 formed in the opening part 23. When the second etch process is performed using the CMP, after a sacrificial layer (not shown) fills in the opening part 23, the CMP is performed until the top surface of the insulation layer 22 is exposed in order to form the patterned first magnetic layer 27A.

The first magnetic layer 27A may be formed over the first electrode 24A through the above-mentioned fabricating processes. Here, the second etch process may be performed using the etchback in order to simplify fabricating processes of the MTJ device.

Referring to FIG. 7C, a tunnel insulation layer 28 and a second magnetic layer are formed over an entire surface of the insulation layer 22 including the first magnetic layer 27A. The second magnetic layer means the free layer 29. The tunnel insulation layer 28 and the free layer 29 may be formed not to completely fill the inside of the opening part 23.

The tunnel insulation layer 28 serves as a tunneling barrier between the pinned layer 26A and 29, and may be formed of any one of materials including an insulation characteristic. For example, the tunnel insulation layer 28 may be formed of MgO.

The free layer 29 has a magnetization direction changed according to a magnetic field or STT, and may be formed of a ferromagnetic material. Additionally, the free layer 29 may be formed of a SAF layer where a ferromagnetic layer, an anti-ferromagnetic coupling spacer layer, and a ferromagnetic layer are sequentially stacked.

The free layer 29 and the tunnel insulation layer 28 formed over the top surface of the insulation layer 22 are selectively etched to leave the tunnel insulation layer 28 and the free layer 29 on the lower sidewall of the opening 23. Hereafter, an etch process for patterning the tunnel insulation layer 28 and the free layer 29 is simply called a third etch process. Additionally, the reference number of the patterned tunnel insulation layer 28 is changed into 28A. The reference number of the free layer 29 is changed into 29A.

The third etch process may be performed using the same method as the first etch process, that is, the etchback or the CMP. When the third etch process is performed using the etchback, it is desirable that the shallow etchback is used to prevent the damage of the free layer 29 formed in the opening part 23. When the third etch process is performed using the CMP, after a sacrificial layer (not shown) is filled in the opening part 23, the CMP process is performed until the top surface of the insulation layer 22 is exposed in order to form the patterned free layer 29A and tunnel insulation layer 28A.

The tunnel insulation layer 28A and the free layer 29A may be formed over the first magnetic layer 27A through the above-mentioned fabricating processes. The first electrode 24A, the pinning layer 25A, the pinned layer 26A, and the tunnel insulation layer 28A are partially exposed, and the surface of the free layer 29A is exposed during the third etch process. Therefore, it is desirable that the third etch process is performed using the CMP, in order to prevent the damage of the free layer 29A which is caused by dry etch and electrical characteristic deterioration of the MTJ device which is caused by a conductive etch byproduct occurring during the etch process.

Therefore, a MTJ layer 30 may be formed in the opening part 23 and may have a cylindrical shape where the pinning layer 25A, the pinned layer 26A, the tunnel insulation layer 28A, and the free layer 29A are sequentially stacked with a predetermined thickness.

As described above, the first magnetic layer 27 is formed and etched to form the patterned first magnetic layer 27A, and the tunnel insulation layer 28 and the free layer 29 are sequentially formed over the patterned first magnetic layer 27A and etched to form the patterned tunnel insulation layer 28A and the patterned free layer 29A by using two-step etching process. However, the first magnetic layer 27, the tunnel insulation layer 28 and the free layer 29 may be sequentially formed over the first electrode 24A, and the first magnetic layer 27, the tunnel insulation layer 28 and the free layer 29 may be etched to form the patterned first magnetic layer 27A, the patterned tunnel insulation layer 28A and the patterned free layer 29A, respectively, by using one-step etching process.

Referring to FIG. 7D, a second electrode 32 is formed to fill the empty space of the opening part 23. Here, the second electrode 32 may fill only the empty space of the opening part 23, or may simultaneously fill the empty space of the opening part 23 and cover the top surface of the insulation layer 22 in order to connect the MTJ layers 30 formed in each opening part 23.

The second electrode 32 may be formed of the same material as the first electrode 24A. The second electrode 32 may be formed of a conductive material, for example, a metal material or a metal compound. The metal material may include Ti, Ta, Pt, Cu, W, or Al. The metal compound may include TiN, TaN, or WSi.

Through the above mentioned fabricating process, the MTJ device having a concave structure of a pillar form can be completed.

As mentioned above, since the present invention forms the MTJ device in the opening part 23 having a predetermined width, a desired interval between adjacent MTJ devices can be obtained. Through this, interference phenomenon and electrical short can be prevented between adjacent MTJ devices.

Furthermore, since the present invention forms each thin layer constituting the MTJ layer 30 through a plurality of depositions and etch processes, characteristic deterioration which is caused by a conductive etch byproduct can be prevented.

The present invention based on the above-mentioned object resolving means provides the MTJ device having a concave structure of a pillar shape, such that the formation of the MTJ device having a slant sidewall can be prevented and a desired interval between adjacent MTJ devices can be obtained. Through this, interference phenomenon and electrical short between MTJ devices can be prevented. Moreover, the present invention can improve the integration degree and characteristics of the MTJ device.

Moreover, the memory cell of the present invention includes a pillar-type MTJ device that can be highly integrated, the integration degree of the memory cell is improved, and power consumption can be reduced at the same time.

Furthermore, the present invention forms an MTJ layer through a plurality of depositions and etch processes, such that characteristic deterioration of the MTJ device which is caused by conductive etch byproduct can be prevented.

While the present invention has been described with respect to the specific embodiments, it will be apparent to those skilled in the art that various changes and modifications may be made without departing from the spirit and scope of the invention as defined in the following claims.

What is claimed is:

1. A method for fabricating a magnetic tunnel junction device, the method comprising:
forming an insulation layer having a plurality of openings;
forming a first electrode over the bottom and the sidewall of an opening of the plurality of openings;
forming a magnetic tunnel junction layer over the first electrode; and
forming a second electrode over the magnetic tunnel junction layer to fill the remaining openings.

2. The method of claim 1, wherein the first electrode and the magnetic tunnel junction layer have a cylindrical shape.

3. The method of claim 1, wherein forming the first electrode comprises:
forming a conductive layer for the first electrode over an entire surface of the insulation layer including the opening; and
leaving the conductive layer for the first electrode over the bottom and the sidewall of the opening by selectively etching the conductive layer formed over the top of the insulation layer.

4. The method of claim 1, wherein forming the magnetic tunnel junction layer comprises:
forming a first magnetic layer over an entire surface of the insulation layer including the first electrode;
leaving the first magnetic layer over the first electrode by selectively etching the first magnetic layer formed over the top of the insulation layer;
sequentially forming a tunnel insulation layer and a second magnetic layer over an entire surface of the insulation layer including the patterned first magnetic layer; and
leaving the second magnetic layer and the tunnel insulation layer over the first magnetic layer by selectively etching the second magnetic layer and the tunnel insulation layer formed over the top of the insulation layer.

5. The method of claim 1, wherein forming the magnetic tunnel junction layer comprises:
sequentially forming a first magnetic layer, a tunnel insulation layer and a second magnetic layer over an entire surface of the insulation layer including the first electrode; and
leaving the second magnetic layer, the tunnel insulation layer and the first magnetic layer over the first electrode by selectively etching the second magnetic layer, the tunnel insulation layer and the first magnetic layer formed over the top of the insulation layer.

6. The method of claim 3, wherein selectively etching the conductive layer is performed using shallow etchback or chemical mechanical polishing.

7. The method of claim 6, wherein selectively etching the conductive layer using the chemical mechanical polishing comprises:
forming a sacrificial layer to fill an inside of the opening and to cover the top of the insulation layer;
performing chemical mechanical polishing until the top of the insulation is exposed; and
removing the sacrificial layer.

8. The method of claim 7, wherein the sacrificial layer comprises a carbon containing layer or an oxide layer.

9. The method of claim 8, wherein the carbon containing layer comprises one of photoresist, amorphous carbon, SiOC, and SOC.

10. The method of claim 8, wherein, when the sacrificial layer comprises the carbon containing layer, removing the sacrificial layer is performed using O₂ plasma treatment.

11. The method of claim 8, wherein, when the sacrificial layer comprises the oxide layer, removing the sacrificial layer is performed using a buffered oxide etchant (BOE) solution or an HF solution.
